(19) United States
(12) Patent Application Publication
(10) Pub. No.: US 2013/0298962 A1
(43) Pub. Date: Nov. 14, 2013

(54) PORTABLE MODULAR SOLAR ENERGY POWER GENERATING SYSTEM

(71) Applicant: Jerry Sorgento, Clarksburg, NJ (US)

(72) Inventor: Jerry Sorgento, Clarksburg, NJ (US)

(21) Appl. No.: 13/910,537

(22) Filed: Jun. 5, 2013

Related U.S. Application Data
(63) Continuation-in-part of application No. 12/834,507, filed on Jul. 12, 2010, now abandoned.

(51) Int. Cl. H01L 31/042; H01L 31/045

(52) U.S. Cl. CPC H01L 31/0424; H01L 31/045; H01L 31/0428
USPC 136/245; 136/251

(57) ABSTRACT

A portable modular solar energy generating system is disclosed. The system includes a plurality of modular photovoltaic solar panels that collect solar energy and convert the solar energy to DC power. Each modular panel also contains a micro-inverter for converting the DC power to AC power at the site of the solar energy generating systems. The system is foldable for easy transport to a remote location and can provide readily available electrical power at remote locations.

### BACKGROUND OF THE INVENTION

The present invention is directed to the field of solar energy collecting devices. In particular, the present invention is directed to the field of devices that collect solar energy for use in generating electricity.

Most available solar energy collecting devices are designed to be installed permanently in a particular location that is favorable for the collection of solar energy. However, solar energy can also be a useful source of temporary electricity such as required at construction sites, remote events, emergency areas where electricity is not available in the event of a natural disaster and areas where the electric power grid is interrupted. The available systems are not readily adaptable for temporary remote installations.

Currently available solar energy collecting systems are generally not adapted for easy and quick deployment at remote locations. Thus, the present invention is directed to solving the remote deployment problem of available solar energy power generating systems. A primary object of the present invention is to solve such problems by providing a portable modular solar energy collecting system that can be remotely deployed, quickly installed and provide easy plug in access to AC Power at the remote locations,

### SUMMARY OF THE INVENTION

A portable solar energy electrical generating system comprising a plurality of modular solar energy collecting units wherein each modular solar energy collecting unit comprises a photovoltaic solar panel that converts solar energy to DC electrical power and a micro-inverter for converting the DC electrical power to AC electrical power, a master assembly unit for the plurality of modular solar energy collecting units comprising a frame generally rectangular in shape adapted to receive the plurality of modular solar energy collecting units, a base assembly unit adapted to receive the master assembly unit, and an electrical receptacle located in close proximity to the plurality of modular solar energy collecting units that receives the AC electrical power from the plurality of modular solar energy collecting units and makes the AC electrical power available through standard electrical plugs.

### BRIEF DESCRIPTION OF DRAWINGS

FIG. 1a is a front view of an embodiment of the device of the present invention.

FIG. 1b is a side view of an embodiment of the device of the present invention.

FIG. 2 is a back view of an embodiment of the device of the present invention.

FIG. 3 is a front view illustrating a component of the present invention.

FIG. 4 is a partial cut-away view illustrating a component of the present invention.

FIG. 5 is a detail view illustrating a component of the present invention.

FIG. 6 is a side view illustrating an embodiment of the device of the present invention.

FIG. 7 illustrates an alternate installation of the present invention.

FIG. 8 is a detail view illustrating a component of the present invention.

FIG. 9 is a detail view illustrating a component of the present invention.

FIG. 10a is a back view illustrating a component of the present invention.

FIG. 10b is a side view of the component in FIG. 10a.

FIG. 11a is a front cut-away detail view of a component of the present invention.

FIG. 11b is a side view of the component illustrated in FIG. 11a.

FIG. 12a is a rear view of a component of the present invention.

FIG. 12b is side view of the component illustrated in FIG. 12a.

FIG. 12c is a detail view of part of FIG. 12b.

FIG. 13a is a rear view of a component of the present invention.

FIG. 13b is a top view of a component of the present invention.

### DETAILED DESCRIPTION OF THE PRESENT INVENTION

The present invention will now be described in terms of the presently preferred embodiment thereof as illustrated in the drawings. This description should not be construed as limiting the scope of the appended claims.

The. Solar Generating System 10 is illustrated in the drawings. As shown therein, the system 10 comprises a plurality of modular units 12 that comprise the Solar Generating System 10. Each of the plurality of modular units 12 comprises a photovoltaic solar panel 14 and a micro-inverter 16. The photovoltaic solar panels 14 are commercially available products that collect and convert solar energy into DC electrical power. The micro-inverter 16 converts the DC power generated by the photovoltaic solar panels 14 to AC current which can be used to power conventional electrically powered devices.

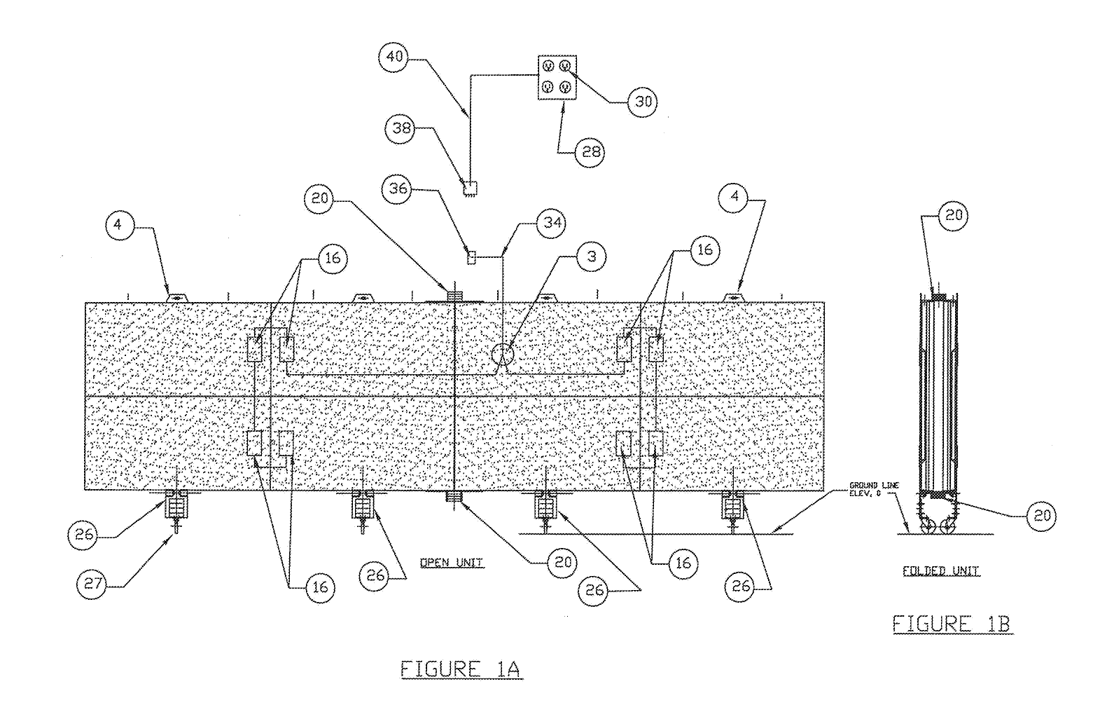

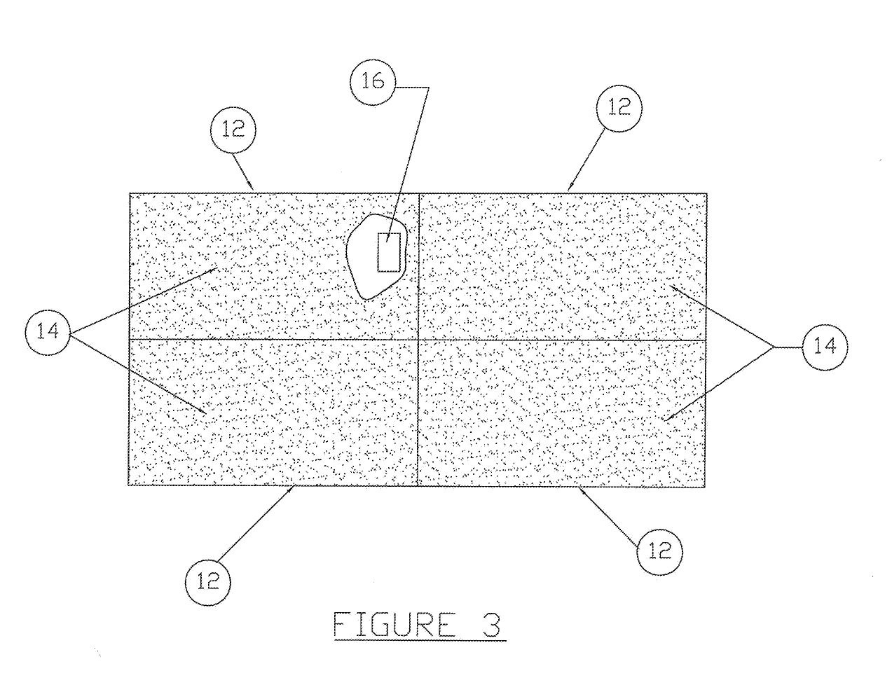

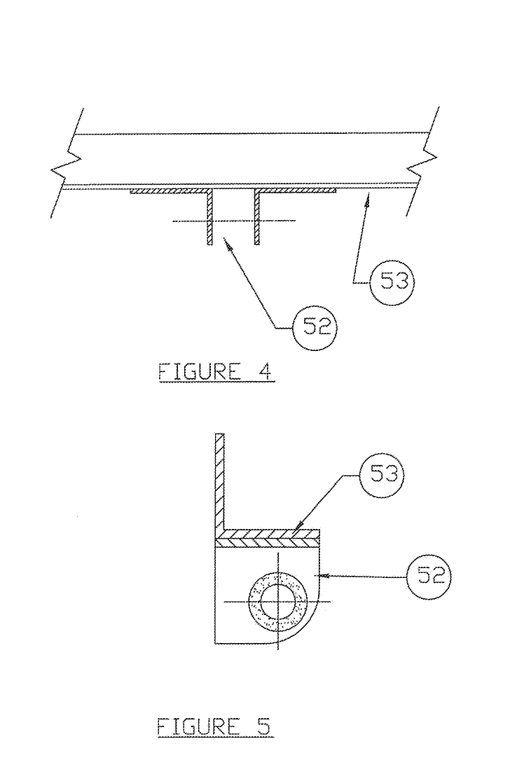

FIG. 3 illustrates a system whereby the number of modular units 12 is 4 although a greater or lesser number of the modular units 12 can be incorporated using the same principles described herein. FIG. 1a illustrates a system whereby the number of modular units is 8. The amount of power produced will vary depending upon the overall size of the Solar Generating System 10 and the number of modular units 12 incorporated therein.

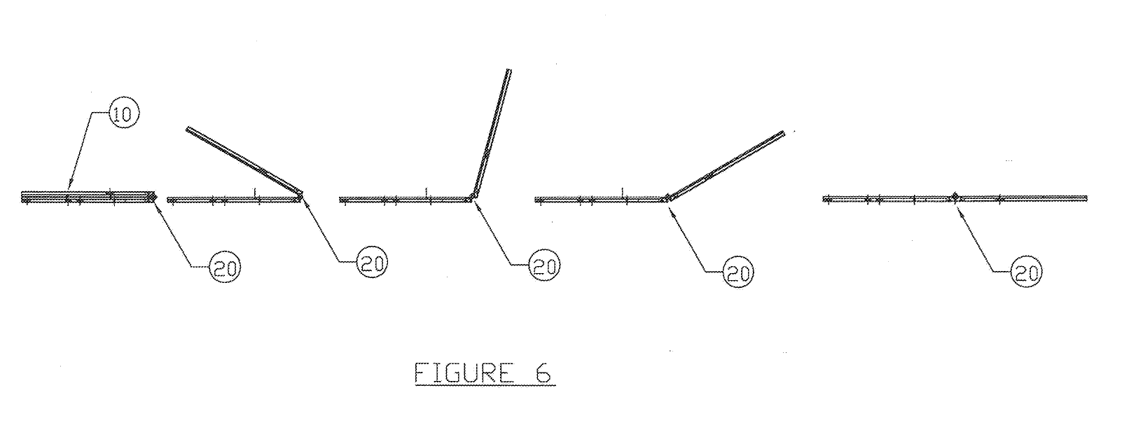

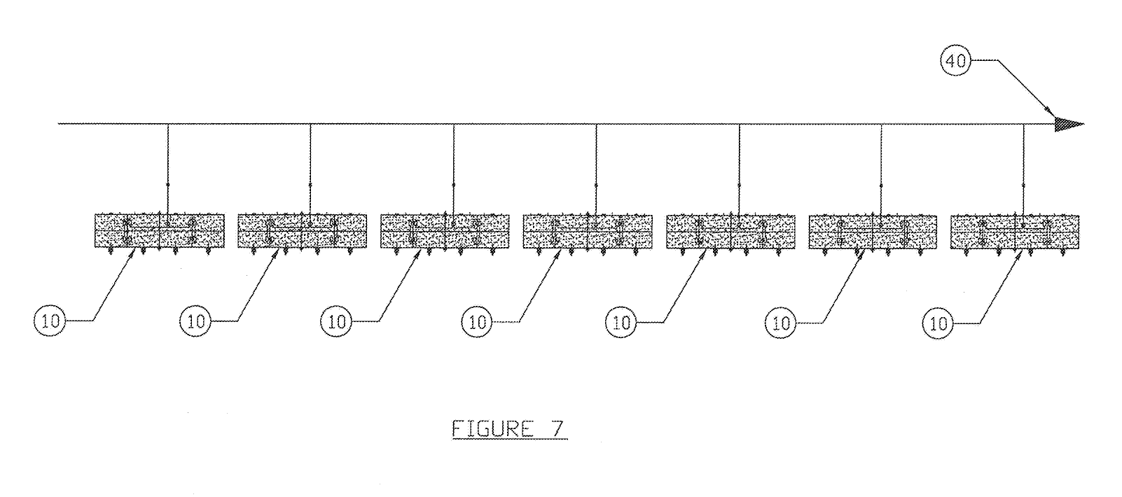

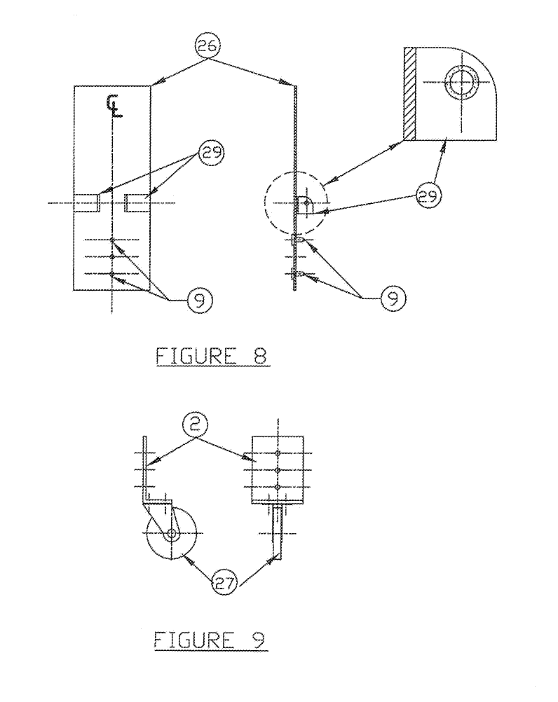

As shown in FIG. 1a, the Solar Generating System 10 comprises a hinge 20. The hinge 20 allows the system to fold flat for easy transport as illustrated in FIG. 1a. The front sides of each modular unit 12 do not contact each other when folded for storage and transport. The front sides of the modular units 12 are the sides that face the sun to collect solar energy. At the remote location where the Solar Generating System 10 is to be used, the system 10 is unfolded at the hinge 20 to the fiat position shown in FIG. 6. At that point the system 10 is oriented at the proper angle for collection of solar energy.

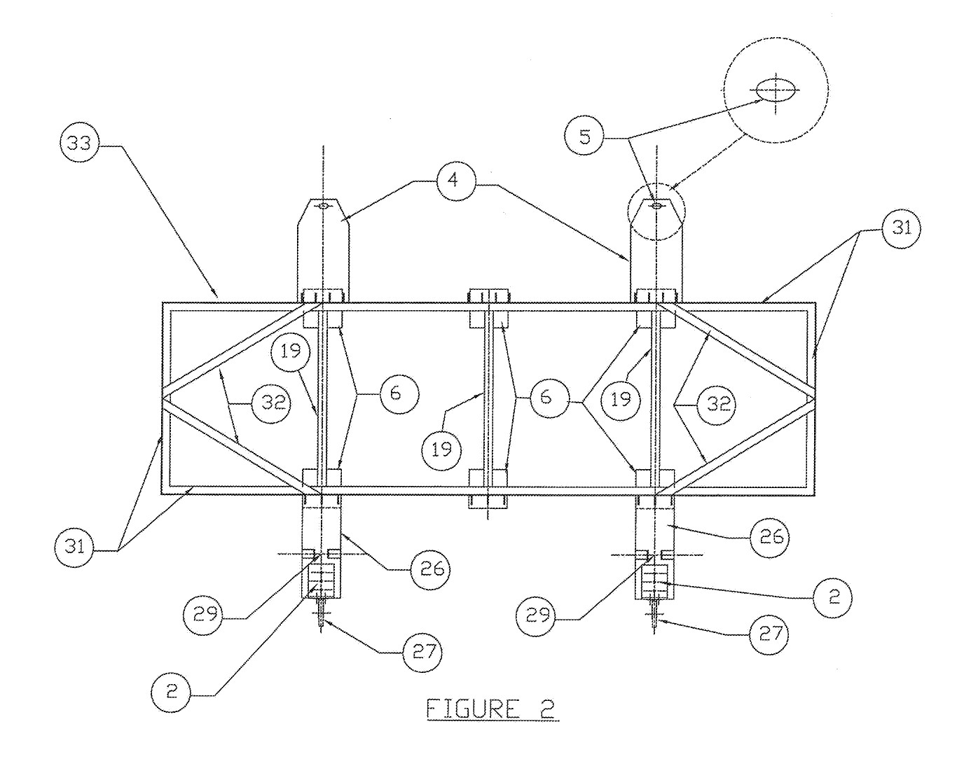

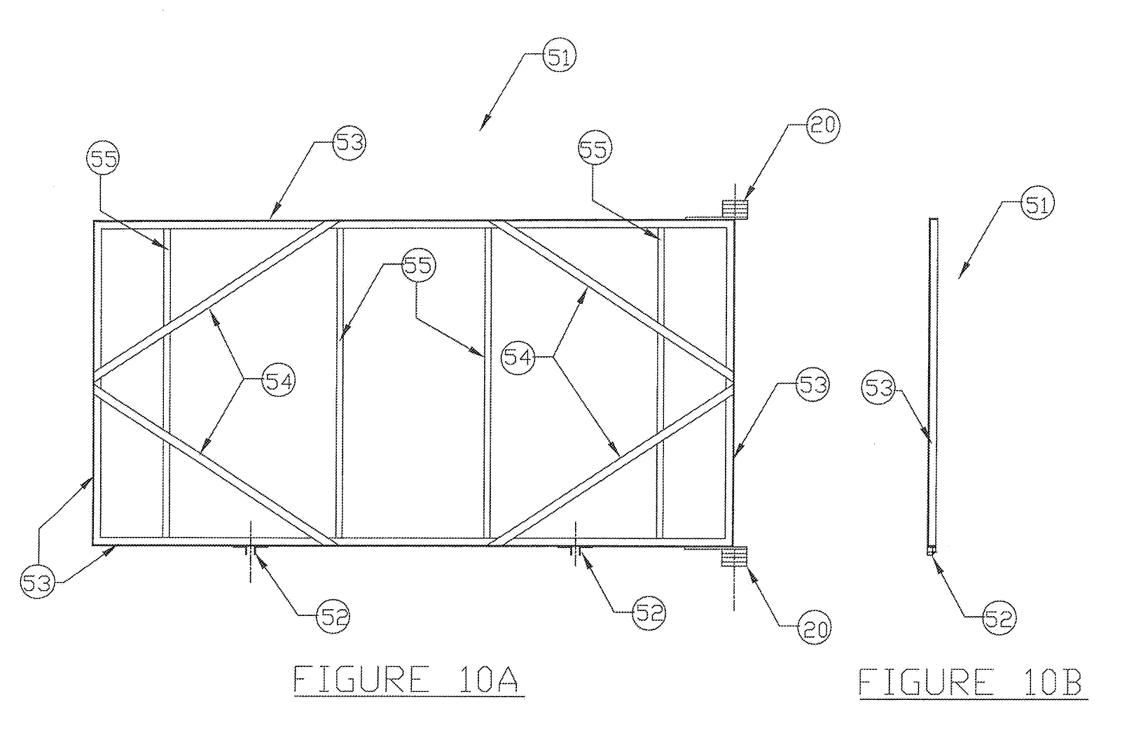

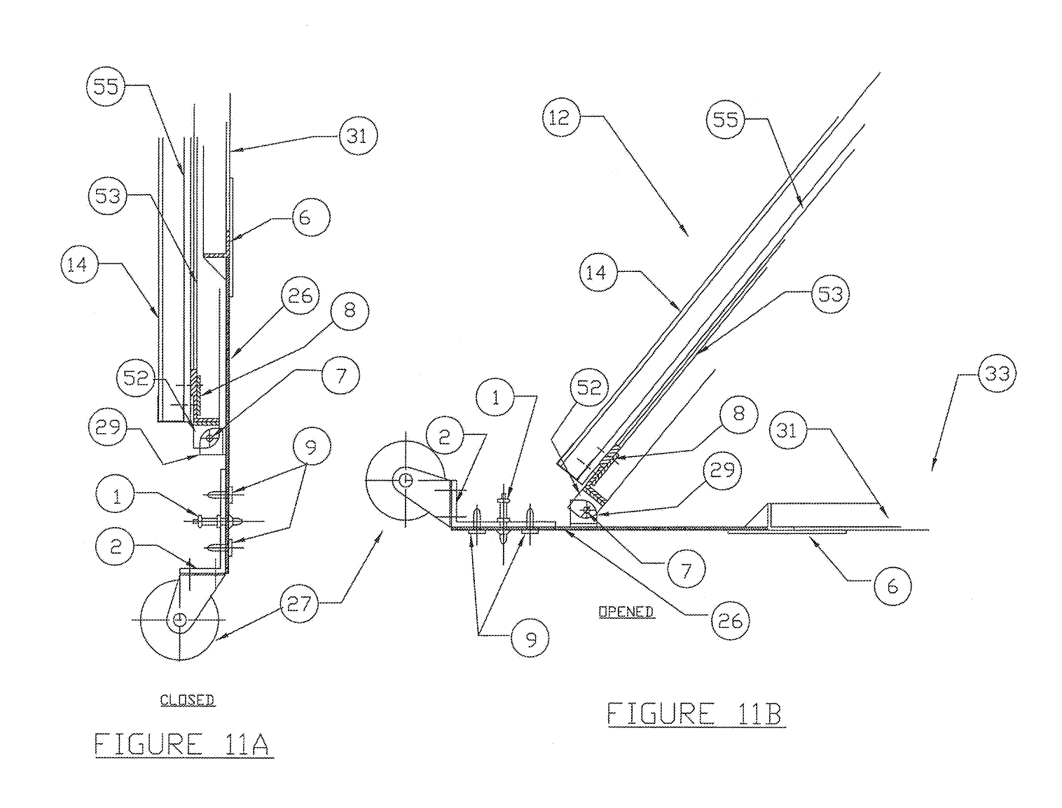

The Solar Generating System 10 further comprises a base assembly 33 as illustrated in detail in FIG. 2. The base assembly 33 comprises a series of support angles 31 that form a generally rectangular configuration. In addition, the base assembly 33 comprises gussets 32 mounted to the support angles 31 and a. plurality of support plates 6. Mounted to the bottom of the base assembly 33 are hinge plate assemblies 26. Each hinge plate assembly 26 is further comprised of two locator pins 9 which are to receive the caster support angle 2 to which casters 27 can be mounted. The casters 27 and caster support angle 2 can be mounted in the hinge plate assembly 26 and are used to roll the Solar Generating System 10 into place at its remote location. The casters 27 and caster support angle 2 are mounted to the hinge plate assembly 26 by means of locating pins 9 and then locked in place by locking pin 1 as shown in FIG. 11. The base assembly further comprises a base frame locking plate 37. The base assembly 33 further comprises stabilizers 4. The stabilizers 4 each comprise a slotted opening 5. The slotted opening 5 is adapted to receive a carrying hook so a crane or helicopter can be used to transport the Solar Generating System 10.

The Solar Generating System 10 further comprises a master frame assembly 51 as illustrated in FIG. 10. The master frame assembly 51 comprises a plurality of support angles 53 that form a generally rectangular configuration. The master frame assembly 51 further comprises a plurality of gussets 54, a tongue 8, mounting tie bars 17, master frame locking plate 35, solar module mounting rails 55 and hinge angles 52. The plurality of solar modular units 12 are received in the master frame assembly 51 as illustrated in FIG. 11. The master frame assembly 51 is joined to the base assembly 33 by joining the hinge angles 52 on the main frame assembly 51 to the hinge angles 29 on the base assembly 33. A hinge pin 7 is used to join the hinge angle 52 to the hinge angle 29. The master frame assembly 51 can rotate to a closed or open position with respect to the base assembly 33 as shown in FIGS. 11a and 11b.

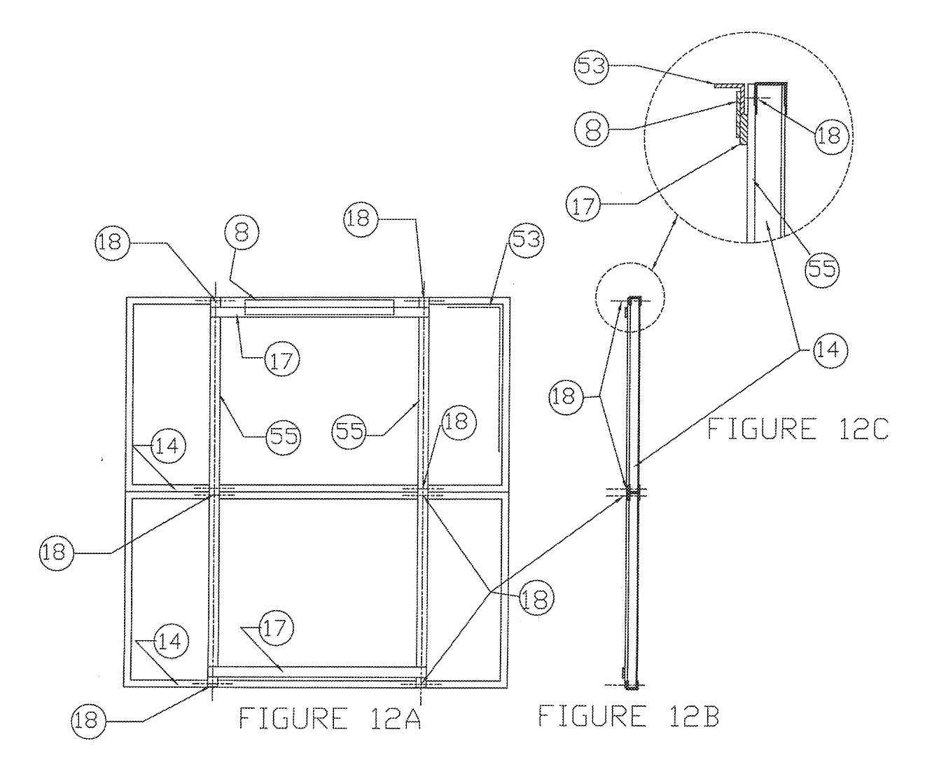

FIGS. 12a and 12b illustrate the attachment of modular units 12 to the mounting rails 55. The modular units 12 are attached to the master frame assembly 51 by a plurality of rivets 18 as shown in FIGS. 12a and 12b. The use of rivets 18 to mount the modular units to the master assembly acts as a deterrent to theft or vandalism of the solar modular units 12 while in use at the remote location. In addition, the casters 27 may be easily removed by removing the locking pins 1 to further deter vandalism or theft.

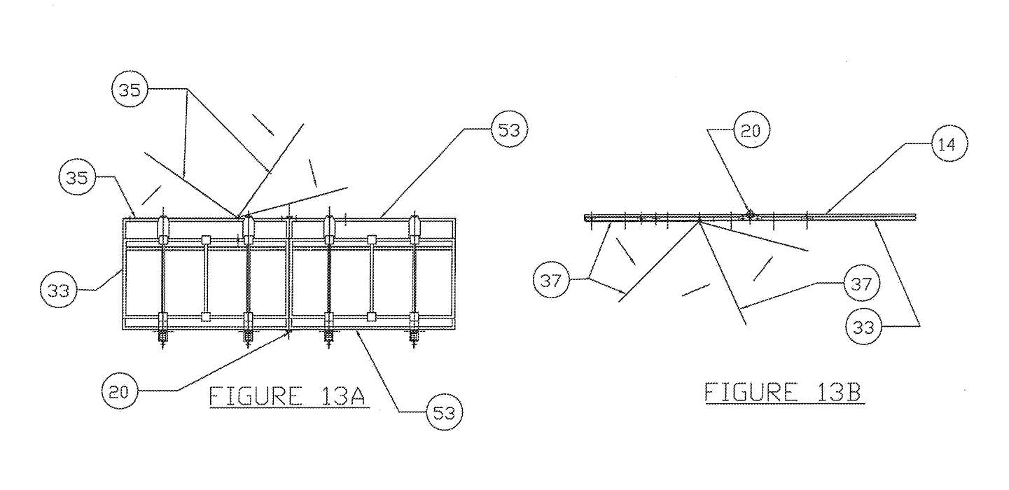

FIGS. 13a and 13b illustrate the use of the master frame locking plate 35 and the base frame locking plate 37. The locking plates are required to keep the master frame assembly 51 and the base assembly 33 locked in place in their respective locked positions with positive locking pins. The locking procedure is done prior to the solar energy generating system 10 being set to the final position and oriented toward the sun to begin gathering solar energy. The locking procedure is done entirely by means of the positive locking pins so that no tools are required.

In available solar panel installations, several modules are connected to each other electrically in series in what is referred to the art as a “string” of modules. The micro-inverter 16 of the present invention is integral with the modular unit 12 as shown in FIG. 5 or alternatively could be mounted under the modular unit 12 on the frame 30. By providing one micro-inverter 16 for each module 12, solar power is converted directly from DC to AC power at each individual solar module 12. Consequently, rather than directing the DC power from a string of modules to a large remote inverter, as in traditional installations, the present Solar Generating System 10 allows for direct delivery of AC power from the micro-inverter 16 to a portable receptacle box 28 located near to the installations. The portable receptacle box 28 is provided with electrical plugs 30 that allow an electrically operated device to be plugged therein at the remote installation location.

FIG. 1 illustrates an installation of one Solar Generating System 10 comprising 4 modular units 12. In this configuration, the AC power output from the micro-inverters 16 are spliced together at a splice box 31. A power cable 34 runs from the splice box 31 to a female, multi-pin weather-tight/weatherproof connector 36. A portable receptacle box 28 is connected to the connector 36 by means of cable 40 with a mating male connecter which is also a multi-pin weather-tight/weatherproof connector 38. FIG. 7 illustrates an alternative configuration wherein 8 Solar Generating Systems 10 are connected in parallel to form a high volume electrical utility feed 40.

In use, it is anticipated that the system 10 will be transported to the remote location requiring power with the Solar Generating System 10 folded at the hinge 20. At the remote location, the system 10 can be rolled into place by means of the casters. The Solar Generating System 10 is then unfolded at the hinge 20. The Solar Generating System 10 is then oriented toward the sun and begins to gather solar energy for conversion to electric power. The photovoltaic cells 14 begin generating DC power that is converted to AC power by the micro-inverters 16. The AC power is then directed to the portable receptacle box 28. AC power will then be immediately available from the plugs 30.

Those of ordinary skill in the art will recognize that the foregoing merely represents an embodiment of the present invention and many modifications may be made thereto without departing from the spirit or scope of the present invention as set forth in the appended claims.

What is claimed is:

1) A portable solar energy electrical generating system comprising:
a) a plurality of modular solar energy collecting units wherein each modular solar energy collecting unit comprises a photovoltaic solar panel that converts solar energy to DC electrical power and a micro-inverter for converting the DC electrical power to AC electrical power;
b) a master assembly unit for the plurality of modular solar energy collecting units comprising a frame generally rectangular in shape adapted to receive the plurality of modular solar energy collecting units;
c) a base assembly unit adapted to receive the master assembly unit; and
d) an electrical receptacle box located in close proximity to the plurality of modular solar energy collecting units that receives the AC electrical power from. the plurality of modular solar energy collecting units and makes the AC electrical power available through standard electrical plugs.

2) The portable solar energy electrical generating system of claim 1 wherein each of the plurality of micro-inverters is integral with the photovoltaic solar panel.

3) The portable solar energy electrical generating system of claim 1 wherein each of the plurality of micro-inverters is mounted to the frame near the respective photovoltaic solar panel.

4) The portable solar energy electric generating system of claim 1 wherein the mounting unit further comprises a hinge so that the system may be reversibly folded about the hinge for transport of the solar energy generating system,

5) The portable solar energy electric generating system of claim 1 wherein the system further comprises casters mounted to the bottom of the system for transport of the system.

6) The portable solar energy electric generating system of claim 1 wherein the system further comprises a plurality of rivets that fix the plurality of modular solar energy collecting units to the master assembly unit.

7) The portable solar energy electric generating system of claim 1 wherein the system further comprises several anti-theft and anti-vandalism mechanisms when placed in service at remote locations wherein the casters are removed, the micro inverters are built into the modular solar energy collecting units and by using rivets to fix the plurality of modular solar energy collecting units to the master assembly.
